(19) United States
(12) Patent Application Publication
(10) Pub. No.: US 2009/0256140 A1
(43) Pub. Date: Oct. 15, 2009

(54) Light-detecting device structure

(75) Inventors: Hsin-Fei Meng, Hsinchu City (TW); Sheng-Fu Horng, Hsinchu City (TW); Yu-Chiang Chao, Bade City (TW)

Correspondence Address: Juan Carlos A. Marquez;c/o Stites & Harbison PLLC, 1199 North Fairfax Street, Suite 900, Alexandria, VA, 22314-1437, US

(73) Assignee: National Chiao Tung University

(21) Appl. No.: 12/153,578

(22) Filed: May 21, 2008

(30) Foreign Application Priority Data
Apr. 10, 2008 (TW) 097113008

(51) Int. Cl. H01L 51/00

(52) U.S. Cl. 257/40; 257/E51.001

(57) ABSTRACT

A light-detecting device structure comprises a substrate, a vertical organic light-emitting transistor and a light-detecting unit, wherein the vertical organic light-emitting transistor is disposed at a first location on the substrate, and the light-detecting unit is disposed at a second location on the substrate, in which the first and the second locations can be spaced out an appropriate distance as needed. The vertical organic light-emitting transistor emits a light to an object, and the light-detecting unit receives a reflected light from the object. The reflected light received is analyzed to determine a distance between the light-detecting device structure and the object, as well as a shape or a composition of the object.

### BACKGROUND OF THE INVENTION

1. Technical Field

The present invention relates to a light-detecting device structure, and more particularly, to a light-detecting device structure using a vertical organic light-emitting transistor as a light source.

2. Description of Related Art

An organic light-emitting diode (OLED) and a light-emitting diode (LED) emit light according to a similar principle that uses semiconductor properties, i.e., an electron is combined with an electron hole to emit a photon. However, the organic light-emitting diode has a much simpler manufacturing process and an advantageously lower cost than the light-emitting diode. The organic light-emitting diode is a film element and can be manufactured at a low temperature. Therefore, the most prominent feature of the organic light-emitting diode is a relatively low dependence on its substrate. In other words, the organic light-emitting diode can be made on a glass substrate or a plastic substrate, so as to form a soft electronic device that can be applied to a large flexible panel. The flexible panel thus formed not only has a desirably small thickness, but is also easy to carry around. Moreover, the flexible panel has such a flexibility that allows it to comply with a shape of an object.

The organic light-emitting diode is a light source with low power-consumption and high brightness, suitable for use in display devices and other electronic device such as a scanner, a printer, etc. In addition, the organic light-emitting diode is different from a traditional electronic component in that the organic light-emitting diode can be made into a soft electronic device that can follow a contour of a book page, or even used on an object having a curved surface, such as a sculpture, so as to scan words or patterns thereon.

A soft scanner is only one of various applications of the organic light-emitting diode. The organic light-emitting diode can also be used as a light source of a light-detecting device, wherein a light emitted by the organic light-emitting diode is emitted to an object to be detected, and wavelengths of a reflected light from the object are analyzed to evaluate a shape of the object, a pattern thereon and a composition thereof. Such a light-detecting device can be further integrated with other electronic devices for measuring a distance between the object and the light-detecting device.

However, when the organic light-emitting diode is used as a light source of a light-detecting device, a transistor is usually combined therewith to drive or control the organic light-emitting diode. Nevertheless, a design composed of the two individual components, i.e., the organic light-emitting diode and the transistor, poses a limitation on a volume of the light-detecting device, so that an overall dimension of the light-detecting device cannot be reduce.

### BRIEF SUMMARY OF THE INVENTION

Therefore, it is an objective of the present invention to provide a light-detecting device structure, wherein a vertical organic light-emitting transistor emits a light to an object to be detected, and a light-detecting unit receives a reflected light from the object, so that the reflected light received by the light-detecting unit can be analyzed to determine a shape or a composition of the object, as well as a distance between the object and the light-detecting device structure. The vertical organic light-emitting transistor is formed by vertically stacking an OLED on a vertical transistor, wherein the OLED is driven by the vertical transistor. Thus, the vertical organic light-emitting transistor can be downsized, thereby further reducing an overall volume of the light-detecting device structure.

To achieve this end, the present invention provides a light-detecting device structure comprising a substrate, a vertical organic light-emitting transistor disposed at a first location on the substrate, and a light-detecting unit disposed at a second location on the substrate, wherein the first and the second location are spaced out an appropriate distance.

Implementation of the present invention provides at least the following advantageous effects:
1. The light-detecting device can be downsized by using the vertical organic light-emitting transistor;
2. The light-detecting device structure formed with the vertical organic light-emitting transistor can be used to improve a scanner, so that scanning can be performed along and in compliance with a shape of an object;
3. With the light-detecting device structure, an absorption spectrum of the object can be analyzed to determine a composition of the object; and
4. The light-detecting device can be used to measure a distance between the light-detecting device and the object.

### BRIEF DESCRIPTION OF THE SEVERAL VIEWS OF THE DRAWINGS

A detailed description of features and advantages of the present invention will be given below, so that a person skilled in the art is allowed to understand and carry out the technical content of the present invention, and can readily comprehend the above-mentioned and other objectives and advantages of the present invention after reading the content disclosed herein and the claims in conjunction with the appended drawings, wherein:

FIGS. 1 to 11 are cross-sectional views of light-detecting device structures according to a first to an eleventh embodiment of the present invention, respectively; and

FIG. 12 illustrates an application of the light-detecting device structure according to the present invention.

### DETAILED DESCRIPTION OF THE INVENTION

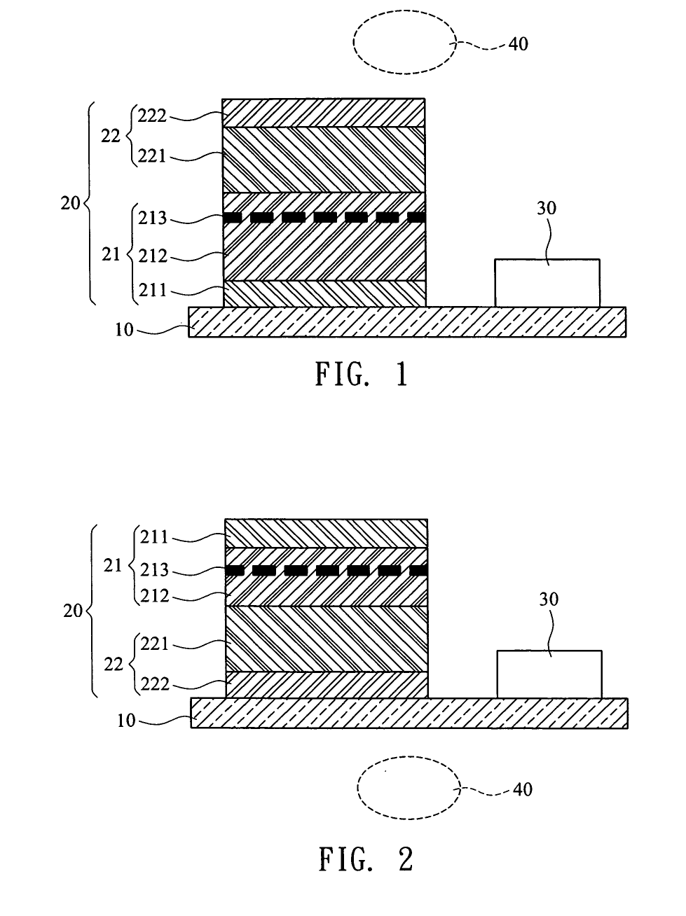

As shown in FIG. 1, a light-detecting device structure according to a first embodiment of the present invention comprises a substrate 10, a vertical organic light-emitting transistor 20 and a light-detecting unit 30.

The substrate 10 can be a transparent substrate that allows light transmission therethrough. More particularly, the substrate 10 can be a glass substrate or a plastic substrate, and can be flexible so as to form a soft electronic device.

The vertical organic light-emitting transistor 20 is disposed at a first location on the substrate 10 for light emitting. Further, the vertical organic light-emitting transistor 20 can have a first vertical transistor 21 and a first OLED 22, or alternatively a second vertical transistor 23 and a second OLED 24.

The first vertical transistor 21 has a first electrode 211, a first organic layer 212 and a second electrode 213.

The first organic layer 212 is stacked on the first electrode 211, and can be selected from the group consisting of a hole injection layer (HIL), a hole transport layer (HTL), a hole blocking layer (HBL), an electron blocking layer (EBL), an electron transport layer (ETL) and an electron injection layer (EIL).

The second electrode 213 is combined in the first organic layer 212, and can be combined in the first organic layer 212 at any location therein, including on top of the first organic layer 212. Further, the second electrode 213 can be used to control a quantity of injected holes or electrons, thereby modulating a light-emitting brightness of the first OLED 22.

The first OLED 22 has a second organic layer 221 and a third electrode 222, wherein the second organic layer 221 is stacked on the first vertical transistor 21. The second organic layer 221 comprises an emission layer (EML), or can further comprise at least one selected from the group consisting of a hole injection layer, a hole transport layer, a hole blocking layer, an electron blocking layer, an electron transport layer, and an electron injection layer, so as to reduce an energy barrier difference between the different layers and increase a light-emitting efficiency of the first OLED 22.

The third electrode 222 is stacked on the second organic layer 221 and can function as a cathode or an anode of the light-detecting device structure. The vertical organic light-emitting transistor 20 is designed in such a way that the second organic layer 221 of the first OLED 22 is stacked vertically on the first vertical transistor 21, wherein the third electrode 222 is stacked on the second organic layer 221.

For instance, the first electrode 211 of the first vertical transistor 21 can be an anode, and is usually made of a material having a relatively high work function, such as gold, platinum, molybdenum oxide/aluminum, PEDOT/molybdenum oxide/aluminum or a combination thereof. Alternatively, the first electrode 211 can be a transparent electrode made of, for example, an indium tin oxide (ITO). Meanwhile, the first organic layer 212 stacked on the first electrode 211 can comprise a hole injection layer and a hole transport layer, wherein the hole injection layer is stacked on the first electrode 211 while the hole transport layer is further stacked on the hole injection layer. The second electrode 213 can be a grid combined in the hole transport layer at any location therein, including on top of the hole transport layer. Consequently, the third electrode 222 of the first OLED 22 can be a cathode, which is usually made of a composite metal material having a relatively low work function, such as calcium/aluminum, lithium fluoride/aluminum, cesium fluoride/aluminum, barium/aluminum or a combination thereof, to increase the electron injection efficiency.

The second electrode 213 serves to control the quantity of holes injected into the first OLED 22. Through a voltage modulation of the appropriate second electrode 213 and the third electrode 222, the holes are allowed to pass through the second electrode 213 and be injected into the first OLED 22. The holes injected into the first OLED 22 will recombined, in the second organic layer 221, with electrons injected from the third electrode 222. Recombination of the holes and the electrons allows the emission layer of the second organic layer 221 emits light.

As another example, the first electrode 211 of the first vertical transistor 21 can be a cathode, which is usually made of a composite metal material having a relatively low work function, such as calcium/aluminum, lithium fluoride/aluminum, cesium fluoride/aluminum, barium/aluminum or a combination thereof, to increase the electron injection efficiency. Meanwhile, the first organic layer 212 stacked on the first electrode 211 can be an electron transport layer, which is stacked on the first electrode 211. The second electrode 213 can be a grid and combined in the electron transport layer at any location therein, including on top of the electron transport layer. Consequently, the third electrode 222 of the first OLED 22 can be an anode, which is usually made of a material having a relatively high work function, such as gold, platinum, aluminum/molybdenum oxide, aluminum/molybdenum oxide/PEDOT or a combination thereof. Alternatively, the third electrode 222 can be a transparent electrode made of an indium tin oxide, for example.

In this arrangement, the second electrode 213 serves to control the quantity of electrons injected into the first OLED 22. Through a voltage modulation of the appropriate second electrode 213 and the third electrode 222, the electrons are allowed to pass through the second electrode 213 and be injected into the first OLED 22. The electrons injected into the first OLED 22 will recombined, in the second organic layer 221, with holes injected from the third electrode 222. Recombination of the holes and the electrons allows the emission layer of the second organic layer 221 emits light.

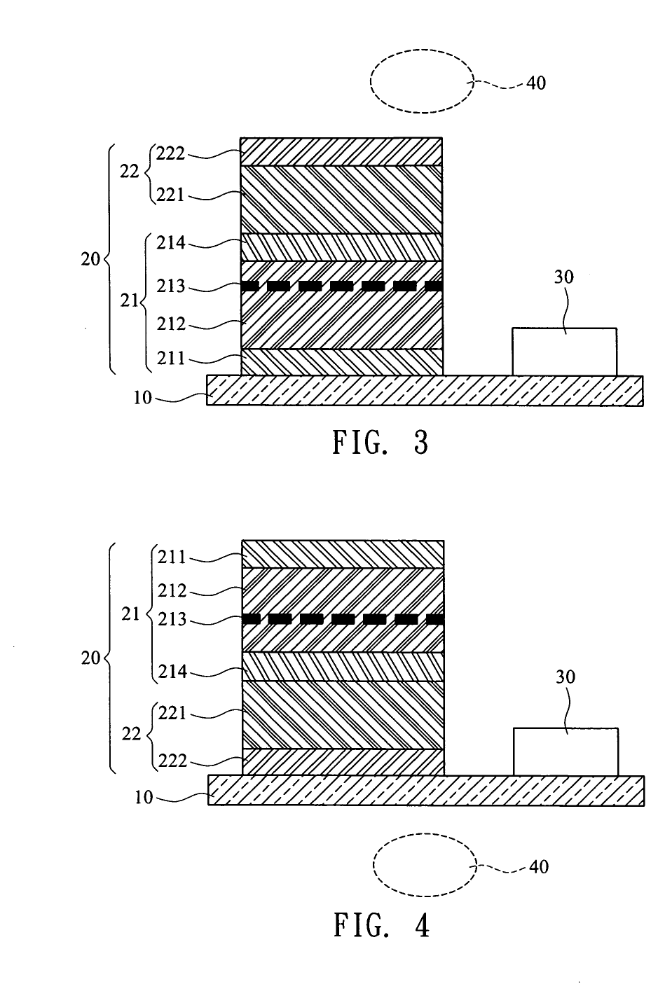

As shown in FIGS. 1 and 3, the substrate 10 can be disposed adjacent to the first vertical transistor 21, wherein the substrate 10 can be a transparent substrate, a glass substrate, a plastic substrate, etc. In other words, the first electrode 211 of the first vertical transistor 21 can be disposed on the transparent substrate. When the third electrode 222 is a very thin metal electrode, the light emitted from the emission layer of the second organic layer 221 will be emitted upwards through the third electrode 222. Therefore, an object 40 to be detected can be placed above the light-detecting device structure to facilitate detection. Moreover, as the first electrode 211 can also be a transparent electrode, the light emitted from the emission layer of the second organic layer 221 can also be emitted downwards through the first electrode 211, so that the light is emitted both upwards and downwards. Hence, two objects 40 to be detected which are placed above and below the light-detecting device structure, respectively, can be detected at the same time.

Referring to FIGS. 2 and 4, the substrate 10 can be disposed adjacent to the first OLED 22, wherein the substrate 10 can be a transparent substrate, a glass substrate, a plastic substrate, etc. In other words, the third electrode 222 of the first OLED 22 can be disposed on the transparent substrate. Now that the third electrode 222 can be a very thin metal electrode or a transparent electrode, when the emission layer of the second organic layer 221 emits a light, the light will be emitted downwards through both the third electrode 222 and the transparent substrate. Thus, an object 40 to be detected can be placed below the light-detecting device structure for detection. The aforementioned transparent substrate can also be flexible, so that the light-detecting device structure can be applied to a soft electronic device.

As shown in FIGS. 3 and 4, the vertical organic light-emitting transistor 20 can further comprise a fourth electrode 214 which is disposed between the first organic layer 212 of the first vertical transistor 21 and the second organic layer 221 of the first OLED 22, and serves as a cathode or an anode. The fourth electrode 214 can be made of a metal having a low work function, such as aluminum, silver, etc. Alternatively, the fourth electrode 214 can be made of a material having a multilayer structure comprising a highly conductive polymer (such as PEDOT) or a metal and other materials, such as aluminum/molybdenum oxide, aluminum/molybdenum oxide/PEDOT, gold/PEDOT, etc.

The fourth electrode 214 can serve as a cathode or an anode in the light-detecting device structure. For instance, when the first electrode 211 of the first vertical transistor 21 is an anode, the second electrode 213 is a grid, and the third electrode 222 of the first OLED 22 is a cathode, the fourth electrode 214 can be an anode. Similarly, when the first electrode 211 of the first vertical transistor 21 is a cathode, the second electrode 213 is a grid, and the third electrode 222 of the first OLED 22 is an anode, the fourth electrode 214 can be a cathode.

Alternatively, the vertical light-emitting transistor 20 can comprise the second vertical transistor 23 and the second OLED 24.

The second vertical transistor 23 has a fifth electrode 231, a third organic layer 232, a first insulation layer 233 and a sixth electrode 234, wherein the third organic layer 232 is stacked on the fifth electrode 231, and can be selected from the group consisting of a hole injection layer, a hole transport layer, a hole blocking layer, an electron blocking layer, an electron transport layer and an electron injection layer. The first insulation layer 233 is stacked between the third organic layer 232 and the sixth electrode 234, while the sixth electrode 234 is stacked on the first insulation layer 233.

The second OLED 24 has a fourth organic layer 241 and a seventh electrode 242. The fourth organic layer 241 comprises an emission layer, or can further comprise at least one selected from the group consisting of a hole injection layer, a hole transport layer, a hole blocking layer, an electron blocking layer, an electron transport layer and an electron injection layer, wherein different combinations thereof can be used to reduce an energy barrier difference between the different layers and increase a light-emitting efficiency of the second OLED 24.

The seventh electrode 242 is stacked on the fourth organic layer 241 and can function as a cathode or an anode of the light-detecting device structure. The vertical organic light-emitting transistor 20 is designed in such a way that the fourth organic layer 241 of the second OLED 24 is stacked vertically on the second vertical transistor 23, wherein the seventh electrode 242 is stacked on the fourth organic layer 241.

The light-detecting device structure can have the following cathode/anode arrangements. For example, the fifth electrode 231 of the second vertical transistor 23 can be an anode, which is usually made of a material having a relatively high work function, such as gold, platinum, molybdenum oxide/aluminum, PEDOT/molybdenum oxide/aluminum or a combination thereof. Alternatively, the fifth electrode 231 can be a transparent electrode made of an indium tin oxide, for instance. Meanwhile, the third organic layer 232 stacked on the fifth electrode 231 can comprise a hole injection layer and a hole transport layer, wherein the hole injection layer is stacked on the fifth electrode 231 while the hole transport layer is further stacked on the hole injection layer. The first insulation layer 233 can be stacked on the hole transport layer first before the sixth electrode 234 is stacked on the first insulation layer 233, wherein the sixth electrode 234 can be a base. The seventh electrode 242 of the second OLED 24 can be a cathode, which is usually made of a composite metal material having a relatively low work function, such as calcium/aluminum, lithium fluoride/aluminum, cesium fluoride/aluminum, barium/aluminum or a combination thereof, to increase the electron injection efficiency.

When the first insulation layer 233 and the sixth electrode 234 have appropriate thicknesses, holes injected from the fifth electrode 231 can tunneling the first insulation layer 233 and then pass through the sixth electrode 234 ballistically. By controlling a current in the sixth electrode 234, a majority of the holes will be injected into the fourth organic layer 241 through the sixth electrode 234 without flowing to the sixth electrode 234.

The holes injected into the fourth organic layer 241 through the sixth electrode 234 will recombined, in the fourth organic layer 241, with electrons injected from the seventh electrode 242, thereby allowing the emission layer of the fourth organic layer 241 to emit a light. The current in the sixth electrode 234 can be modulated to control a quantity of holes entering the second OLED 24, thereby controlling a light-emitting intensity of the second OLED 24.

As another example, the fifth electrode 231 of the second vertical transistor 23 can be a cathode, which is usually made of a metal material having a relatively low work function, such as calcium/aluminum, lithium fluoride/aluminum, cesium fluoride/aluminum, barium/aluminum or a combination thereof, to increase the electron injection efficiency. In addition, the third organic layer 232 stacked on the fifth electrode 231 can comprise an electron transport layer, which is stacked on the fifth electrode 231. The first insulation layer 233 can be stacked on the electron transport layer first before the sixth electrode 234 is stacked on the first insulation layer 233, wherein the sixth electrode 234 can be a base. The seventh electrode 242 of the second OLED 24 can be an anode, which is usually made of a material having a relatively high work function, such as gold, platinum, aluminum/molybdenum oxide, aluminum/molybdenum oxide/PEDOT or a combination thereof. Alternatively, the seventh electrode 242 can be a transparent electrode made of, for example, an indium tin oxide.

Similarly, when the first insulation layer 233 and the sixth electrode 234 have appropriate thicknesses, electrons injected from the fifth electrode 231 can tunneling the first insulation layer 233 and then pass through the sixth electrode 234 ballistically. The current in the sixth electrode 234 can be controlled, so that a majority of the electrons are injected into the fourth organic layer 241 through the sixth electrode 234 without flowing to the sixth electrode 234.

The electrons injected into the fourth organic layer 241 through the sixth electrode 234 will recombined, in the fourth organic layer 241, with holes injected from the seventh electrode 242, thereby allowing the emission layer of the fourth organic layer 241 to emit a light. Therefore, the current in the sixth electrode 234 can be modulated to control a quantity of electrons entering the second OLED 24, thereby controlling the light-emitting intensity of the second OLED 24.

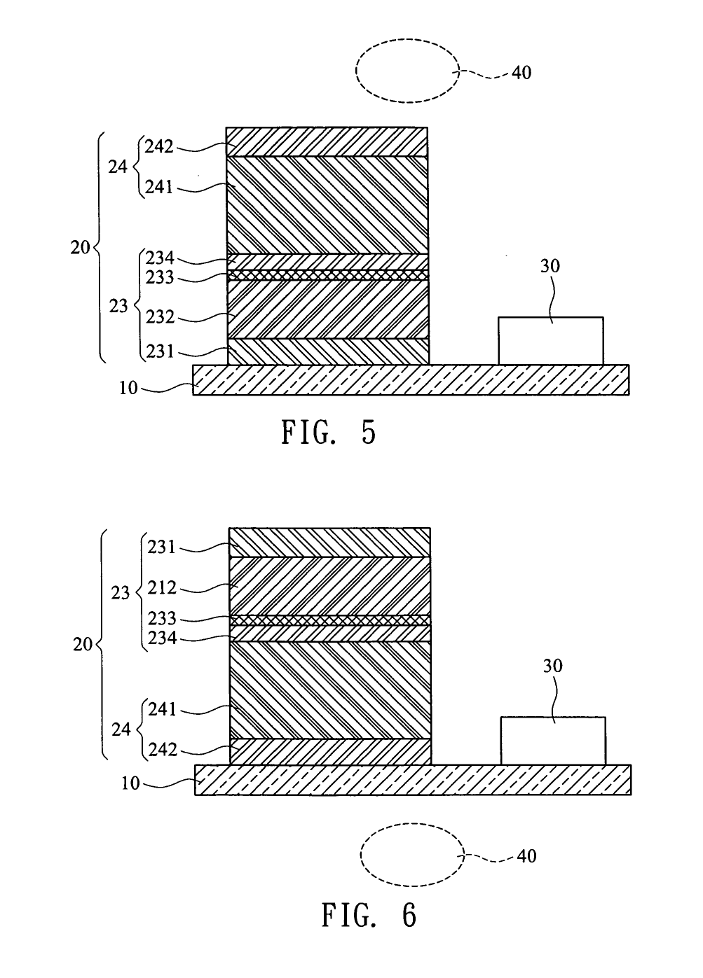

As shown in FIGS. 5, 7 and 8, the substrate 10 can be disposed adjacent to the second vertical transistor 23, wherein the substrate 10 can be a transparent substrate, a glass substrate, a plastic substrate, etc. In other words, the fifth electrode 231 of the second vertical transistor 23 can be disposed on the transparent substrate. As the seventh electrode 242 can be a very thin metal electrode, the light emitted from the second OLED 24 will be emitted upwards through the seventh electrode 242. Therefore, an object 40 to be detected can be placed above the light-detecting device structure to facilitate detection. Moreover, as the fifth electrode 231 can also be a transparent electrode, the light can also be emitted downwards through both the fifth electrode 231 and the substrate 10, so that the light is emitted both upwards and downwards. Hence, two objects 40 to be detected which are placed above and below the light-detecting device structure, respectively, can be detected at the same time.

Referring to FIG. 6, the substrate 10 can also be disposed adjacent to the second OLED 24, wherein the substrate 10 can be a transparent substrate, a glass substrate, a plastic substrate, etc. In other words, the seventh electrode 242 of the second OLED 24 can be disposed on the transparent substrate. Now that the seventh electrode 242 can be a very thin metal electrode or a transparent electrode, when the emission layer of the fourth organic layer 241 emits a light, the light will be emitted downwards through both the seventh electrode 242 and the transparent substrate. Thus, an object 40 to be detected can be placed below the light-detecting device structure for detection. The transparent substrate can also be flexible, so that the light-detecting device structure can be applied to a soft electronic device.

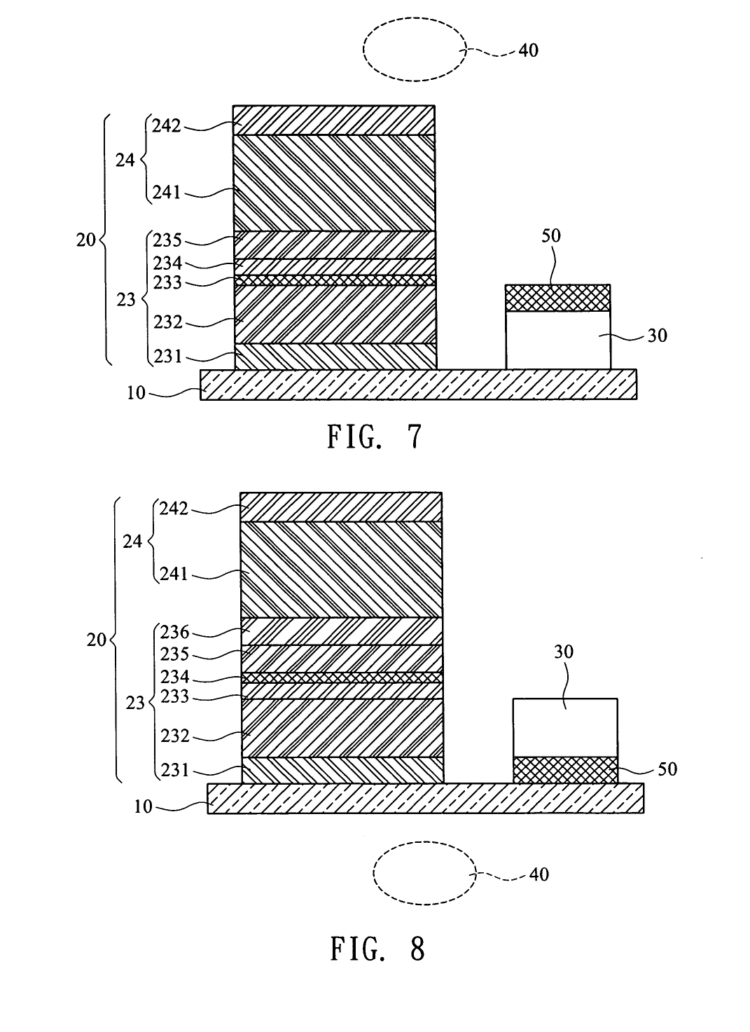

Referring to FIG. 7, in a light-detecting device structure according to a seventh embodiment of the present invention, the second vertical transistor 23 can further comprise a fifth organic layer 235, which can be an electron transport layer, a hole transport layer, an electron blocking layer or a hole blocking layer. In addition, the fifth organic layer 235 can be disposed between the sixth electrode 234 of the second vertical transistor 23 and the fourth organic layer 241 of the second OLED 24.

As shown in FIG. 7, a transparent substrate is disposed adjacent to the second vertical transistor 23, wherein the transparent substrate can be a flexible glass substrate, plastic substrate, etc. However, in another embodiment of the present invention (not shown), the transparent substrate is disposed adjacent to the second OLED 24 while the seventh electrode 242 is a transparent electrode, such that a light emitted from the emission layer of the second OLED 24 can be emitted downwards through both the seventh electrode 242 and the transparent substrate, then onto an object 40.

FIG. 8 illustrates a light-detecting device structure according to an eighth embodiment of the present invention, wherein the vertical organic light-emitting transistor 20 further comprises a fifth organic layer 235 and an eighth electrode 236.

The fifth organic layer 235 can be an electron transport layer, a hole transport layer, an electron blocking layer or a hole blocking layer, and is stacked on the sixth electrode 234. The eighth electrode 236 is stacked on the fifth organic layer 235, so that the fifth organic layer 235 is sandwiched between the sixth electrode 234 and the eighth electrode 236, while the eighth electrode 236 serves as a cathode or an anode. In addition, the fourth organic layer 241 is stacked on the eighth electrode 236. The eighth electrode 236 can be made of a metal having a low work function, such as aluminum, silver, etc. Alternatively, the eighth electrode 236 can be made of a material having a multilayer structure comprising a highly conductive polymer (such as PEDOT) or a metal and other materials, such as aluminum/molybdenum oxide, aluminum/molybdenum oxide/PEDOT, gold/PEDOT, etc.

As mentioned above, the eighth electrode 236 can function as a cathode or an anode in the light-detecting device structure. For instance, when the fifth electrode 231 of the second vertical transistor 23 is an anode, the sixth electrode 234 is a base, and the seventh electrode 242 is a cathode, the eighth electrode 236 can be an anode. Similarly, when the fifth electrode 231 of the second vertical transistor 23 is a cathode, the sixth electrode 234 is a base, and the seventh electrode 242 is an anode, the eighth electrode 236 can be a cathode.

As shown in FIG. 8, a transparent substrate is disposed adjacent to the second vertical transistor 23, wherein the transparent substrate can be a flexible glass substrate, plastic substrate, etc. However, in another embodiment of the present invention (not shown), the transparent substrate is disposed adjacent to the second OLED 24 while the seventh electrode 242 is a transparent electrode, such that a light emitted from the emission layer of the second OLED 24 can be emitted downwards through both the seventh electrode 242 and the transparent substrate, then onto an object 40 to allow a detection to be performed thereon.

As shown in FIGS. 1 to 11, the light-detecting unit 30 is disposed at the second location on the substrate 10, wherein the second location is spaced from the first location by an appropriate distance as needed.

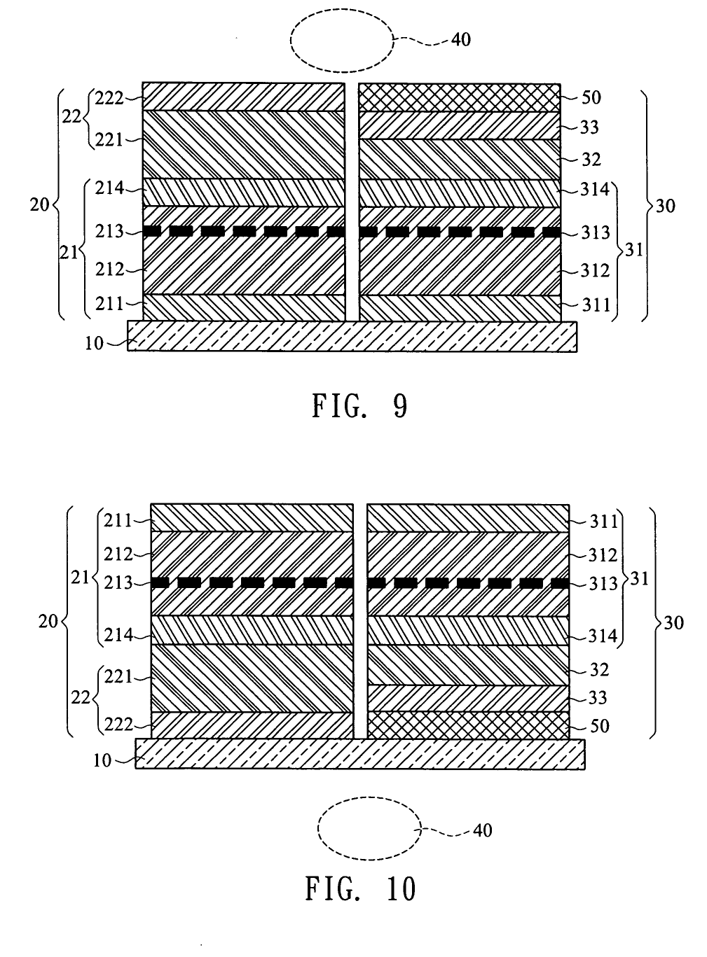

An embodiment of the light-detecting unit 30 is illustrated in FIG. 9, wherein the light-detecting unit 30 comprises a third vertical transistor 31, a light-detecting layer 32 and a twelfth electrode 33.

The third vertical transistor 31 has a ninth electrode 311, a sixth organic layer 312, a tenth electrode 313 and an eleventh electrode 314. The sixth organic layer 312 is stacked on the ninth electrode 311 and can be selected from the group consisting of a hole injection layer, a hole transport layer, a hole blocking layer, an electron blocking layer, an electron transport layer and an electron injection layer. In addition, the tenth electrode 313 can be combined in the sixth organic layer 312 at any location therein, including on top of the sixth organic layer 312. The eleventh electrode 314 is stacked on the sixth organic layer 312 and serves as a cathode or an anode.

The light-detecting layer 32 is vertically stacked on the third vertical transistor 31 and has a structure similar to that of a photodiode. When an external light strikes on the light-detecting layer 32, the light-detecting layer 32 can generate a photoelectric current, which can be read by the underlying third vertical transistor 31. The twelfth electrode 33 is stacked on the light-detecting layer 32 and serves as a cathode or an anode of the light-detecting unit 30.

The light-detecting unit 30 can have the following cathode/anode arrangements. For instance, the ninth electrode 311 of the third vertical transistor 31 can be an anode, which is usually made of a material having a relatively high work function, such as gold, platinum, molybdenum oxide/aluminum, PEDOT/molybdenum oxide/aluminum or a combination thereof Alternatively, the ninth electrode 311 can be a transparent electrode made of an indium tin oxide, for example. Meanwhile, the sixth organic layer 312 stacked on the ninth electrode 311 can comprise a hole injection layer and a hole transport layer, wherein the hole injection layer is stacked on the ninth electrode 311 while the hole transport layer is further stacked on the hole injection layer. The tenth electrode 313 can be a grid and combined in the hole transport layer at any location therein, including on top of the hole transport layer. Further, the eleventh electrode 314 is stacked on the sixth organic layer 312 and can serve as an anode, which can be made of a material having a multilayer structure comprising a highly conductive polymer (such as PEDOT) or a metal and other materials, such as aluminum/molybdenum oxide, aluminum/molybdenum oxide/PEDOT, gold/PEDOT, etc. Thus, the twelfth electrode 33 can be a cathode, which is usually made of a composite metal material having a relatively low work function, such as calcium/aluminum, lithium fluoride/aluminum, cesium fluoride/aluminum, barium/aluminum or a combination thereof, to increase the electron injection efficiency.

The tenth electrode 313 serves to control a quantity of holes injected into the light-detecting layer 32. Through a voltage modulation of the appropriate tenth electrode 313 and the twelfth electrode 33, the holes are allowed to pass through the tenth electrode 313 and reach the eleventh electrode 314. At this time, the third vertical transistor 31 is in a low-resistance state, allowing an external circuit to read the photoelectric current in the light-detecting layer 32, thereby determining whether or not the light-detecting layer 32 has detected light.

As another example, the ninth electrode 311 of the third vertical transistor 31 can be a cathode, which is usually made of a composite metal material having a relatively low work function, such as calcium/aluminum, lithium fluoride/aluminum, cesium fluoride/aluminum, barium/aluminum or a combination thereof, to increase the electron injection efficiency. Meanwhile, the sixth organic layer 312 stacked on the ninth electrode 311 can be an electron transport layer, which is stacked on the ninth electrode 311. In addition, the tenth electrode 313 can be a grid combined in the electron transport layer at any location therein, including on top of the electron transport layer. Further, the eleventh electrode 314 is stacked on the sixth organic layer 312 and can serve as a cathode, which can be made of a material such as aluminum, silver, etc. Thus, the twelfth electrode 33 can be an anode, which is usually made of a material having a relatively high work function, such as gold, platinum, aluminum/molybdenum oxide, aluminum/molybdenum oxide/PEDOT or a combination thereof. Alternatively, the twelfth electrode 33 can be a transparent electrode made of an indium tin oxide, for example.

In this arrangement, the tenth electrode 313 serves as a switch for controlling the third vertical transistor 31. When holes are under a voltage modulation of the appropriate tenth electrode 313, the third vertical transistor 31 can enter an on-state, wherein the third vertical transistor 31 is in a low-resistance state, so that the external circuit can read the photoelectric current in the light-detecting layer 32, thereby determining whether or not the light-detecting layer 32 has detected light.

As shown in FIG. 9, the substrate 10 can be disposed adjacent to the first vertical transistor 21 and the third vertical transistor 31, wherein the substrate 10 can be a transparent substrate, a glass substrate, a plastic substrate, etc. In other words, the first electrode 211 of the first vertical transistor 21 and the ninth electrode 311 of the third vertical transistor 31 can be disposed on the transparent substrate. When a light is emitted upward from the emission layer of the second organic layer 221 and there is an object 40 to be detected, the light will be reflected by the object 40 to t the filter 50. After the light pass through the filter 50, the light will reach the light-detecting layer 32.

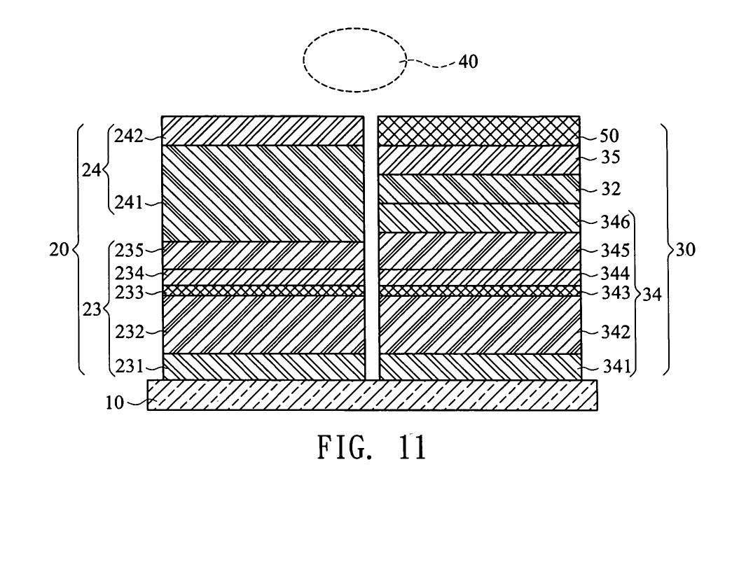

As shown in FIG. 10, the substrate 10 can also be disposed adjacent to the first OLED 22 and the twelfth electrode 33, wherein the substrate 10 can be a transparent substrate, a glass substrate, a plastic substrate, etc. In other words, the third electrode 222 of the first OLED 22 can be disposed on the transparent substrate. Now that the third electrode 222 can be a very thin metal electrode or a transparent electrode, when the emission layer of the second organic layer 221 emits a light, the light can also be emitted downwards through the third electrode 222 and the transparent substrate sequentially. If an object 40 to be detected exists, the object 40 will reflect the light to the twelfth electrode 33. As the twelfth electrode 33 can also be a transparent electrode, the light will be allowed to pass through the twelfth electrode 33 and reach the light-detecting layer 32.

Alternatively, the light-detecting unit 30 can comprise a hot carrier transistor 34, the light-detecting layer 32 and a thirteenth electrode 35.

The hot carrier transistor 34 has an emitter 341, a seventh organic layer 342, a second insulation layer 343, a base 344, an eighth organic layer 345 and a collector 346, wherein the seventh organic layer 342 is stacked on the emitter 341 and can be selected from the group consisting of a hole injection layer, a hole transport layer, a hole blocking layer, an electron blocking layer, an electron transport layer and an electron injection layer. The second insulation layer 343 is stacked between the seventh organic layer 342 and the base 344, while base 344 is stacked on the second insulation layer 343. In addition, the eighth organic layer 345 is stacked on the base 344 and can be selected from the group consisting of an electron transport layer, a hole transport layer, an electron blocking layer and a hole blocking layer. Meanwhile, the collector 346 is stacked on the eighth organic layer 345.

The light-detecting layer 32 is vertically stacked on the hot carrier transistor 34 and has a structure similar to that of a photodiode. When an external light strikes on the light-detecting layer 32, electrons and holes in the light-detecting layer 32 will separate and generate a photoelectric current variation. The thirteenth electrode 35 is stacked on the light-detecting layer 32 and serves as a cathode or an anode of the light-detecting unit 30.

The light-detecting unit 30 can have the following cathode/anode arrangements. For instance, the emitter 341 of the hot carrier transistor 34 can be an anode, which is usually made of a material having a relatively high work function, such as gold, platinum, molybdenum oxide/aluminum, PEDOT/molybdenum oxide/aluminum or a combination thereof. Alternatively, the emitter 341 can be a transparent electrode made of an indium tin oxide, for example. Meanwhile, the seventh organic layer 342 stacked on the emitter 341 can comprise a hole injection layer and a hole transport layer, wherein the hole injection layer is stacked on the emitter 341 while the hole transport layer is further stacked on the hole injection layer. The second insulation layer 343 can be stacked on the hole transport layer before the base 344 is stacked on the second insulation layer 343. Further, the eighth organic layer 345 stacked on the base 344 can comprise a hole injection layer and a hole transport layer, wherein the hole injection layer is stacked on the base 344 while the hole transport layer is further stacked on the hole injection layer. The collector 346 can be stacked on the hole injection layer and serve also as an anode, which is made of a same material as the emitter 341.

The thirteenth electrode 35 stacked on the light-detecting layer 32 can be a cathode, which is usually made of a composite metal material having a relatively low work function, such as calcium/aluminum, lithium fluoride/aluminum, cesium fluoride/aluminum, barium/aluminum or a combination thereof. When the second insulation layer 343 and the base 344 have appropriate thicknesses, holes injected from the emitter 341 can tunnel the second insulation layer 343 and then pass through the base 344 ballistically. By controlling a current in the base 344, a majority of the holes will be injected into the collector 346 through the base 344 without flowing to the base 344.

When the hot carrier transistor 34 is in a low-resistance state, an external circuit can read a photoelectric current in the light-detecting layer 32 and thereby determine whether or not the light-detecting layer 32 has detected light.

As another example, the emitter 341 of the hot carrier transistor 34 can be a cathode, which is usually made of a metal having a relatively low work function, such as calcium/aluminum, lithium fluoride/aluminum, cesium fluoride/aluminum, barium/aluminum or a combination thereof, to increase the electron injection efficiency. In addition, the seventh organic layer 342 stacked on the emitter 341 can comprise an electron transport layer, which is stacked on the emitter 341. The second insulation layer 343 can be stacked on the electron transport layer before the base 344 is stacked on the second insulation layer 343. Further, the eighth organic layer 345 stacked on the base 344 can comprise an electron transport layer while the collector 346 is stacked on the electron transport layer and serves also as a cathode, which is made of a same material as the emitter 341.

In this arrangement, the thirteenth electrode 35 stacked on the light-detecting layer 32 can be an anode, which is usually made of a material having a relatively high work function, such as gold, platinum, aluminum/molybdenum oxide, aluminum/molybdenum oxide/PEDOT or a combination thereof. Alternatively, the thirteenth electrode 35 can be a transparent electrode made of, for instance, an indium tin oxide. Similarly, when the second insulation layer 343 and the base 344 have appropriate thicknesses, electrons injected from the emitter 341 can tunnel the second insulation layer 343 and then pass through the base 344 ballistically. By controlling a current in the base 344, a majority of the electrons will be injected into the collector 346 through the base 344 without flowing to the base 344.

A voltage modulation of the hot carrier transistor 34 determines whether or not an external circuit is allowed to begin operation with the light-detecting unit 30, thereby specifying a particular light-detecting unit 30 whose photoelectric current variation is to be read.

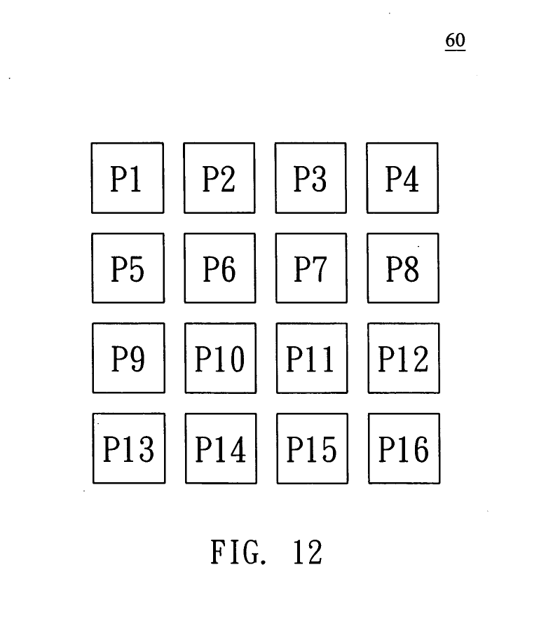

As shown in FIG. 11, a transparent substrate is disposed adjacent to the second vertical transistor 23 and the hot carrier transistor 34, wherein the transparent substrate can be a flexible glass substrate, plastic substrate, etc. However, in another embodiment of the present invention (not shown), the transparent substrate can also be disposed adjacent to the second OLED 24 and a filter 50 while the seventh electrode 242 is a transparent electrode, such that a light emitted from the emission layer of the second OLED 24 can be emitted downwards through both the seventh electrode 242 and the transparent substrate, then onto an object 40. Furthermore, as the thirteenth electrode 35 can be a transparent electrode, a reflected light from the object 40 will pass through the filter 50 and the thirteenth electrode 35 and reach the light-detecting layer 32, thereby causing a photoelectric current variation in the light-detecting layer 32.

Embodiments of the light-detecting unit 30 are shown in FIGS. 1 to 11. The light-detecting unit 30 can be a photodiode, or alternatively, be formed by integrating the light-detecting layer 32 with the third vertical transistor 31 or the hot carrier transistor 34. Moreover, all the embodiments of the light-detecting unit 30 disclosed herein can be selected as needed, and used in combination with the vertical organic light-emitting transistor 20 to achieve the best effect.

When the light-detecting unit 30 is formed by integrating the light-detecting layer 32 with the third vertical transistor 31 or the hot carrier transistor 34, a voltage of the third vertical transistor 31 or the hot carrier transistor 34 can be modulated to determine whether or not an external circuit is allowed to begin operation with the light-detecting unit 30, thereby specifying a particular light-detecting unit 30 whose photoelectric current variation is to be read.

When the vertical organic light-emitting transistor 20 of the light-detecting device structure emits a light and there is no object 40 to be detected, the light-detecting unit 30 will receive no light. As a result, the light-detecting unit 30 will not begin operation and therefore generates no current. However, if an object 40 to be detected is placed in front of the light-detecting device structure, the object 40 will absorb part of the light emitted from the vertical organic light-emitting transistor 20 and reflect the remaining part of the light. In this case, the light-detecting unit 30 will receive a reflected light from the object 40 and begin operation with the light-detecting unit 30 to generate a current variation.

An additional electronic device can be used to calculate the current variation of the light-detecting unit 30 and a time interval at which the vertical organic light-emitting transistor 20 emits light or a light intensity thereof, so that a distance between the object 40 and the light-detecting device structure can be determined. Furthermore, wavelengths of the reflected light received by the light-detecting unit 30 can be compared with wavelengths of the light emitted from the vertical organic light-emitting transistor 20 to obtain an absorption spectrum of the object 40. By analyzing the absorption spectrum, a composition of the object 40 can be determined.

However, the light-detecting unit 30 may directly absorb a light emitted from the vertical organic light-emitting transistor 20, leading to an interference of light. If this happens, the light emitted from the vertical organic light-emitting transistor 20 may be mistaken for a reflected light from the object 40 to be detected, so that a shape, composition, etc. of the object 40 is misjudged. In order to avoid the interference of light, if the light emitted from the vertical organic light-emitting transistor 20 is emitted upwards, a filter 50 can be disposed between the light-detecting unit 30 and the vertical organic light-emitting transistor 20 to absorb a light coming from above. Alternatively, if the light emitted from the vertical organic light-emitting transistor 20 is emitted downwards, the filter 50 can be disposed between the light-detecting unit 30 and the vertical organic light-emitting transistor 20. The light directly emitted form the vertical organic light-emitting transistor 20 to the light-detecting unit 30 will be absorbed by the filters 50. Thus, the filter(s) 50 can filter out the interference of light and thereby increase an accuracy of the light-detecting unit 30 in terms of the wavelengths of light it receives.

Furthermore, the filter 50 can be disposed on top of the twelfth electrode 33, as shown in FIG. 9, or on the light-detecting unit 30 as shown in FIG. 7 and FIG. 8, or between the twelfth electrode 33 and the substrate 10, as shown in FIG. 10. In addition, the filter 50 can also be disposed between the light-detecting layer 32 and the eleventh electrode 314 of the third vertical transistor 31 (not shown).

Moreover, the filter 50 can be disposed on top of the thirteenth electrode 35, as shown in FIG. 11. When a transparent substrate is disposed adjacent to the second OLED 24 and the thirteenth electrode 35, the filter 50 can be disposed between the thirteenth electrode 35 and the substrate 10 (not shown). Besides, the filter 50 can also be disposed between the light-detecting layer 32 and the collector 346 of the hot carrier transistor 34 (not shown).

Furthermore, the vertical organic light-emitting transistor 20 of the light-detecting device structure should emit a light whose wavelengths are not the most sensitive wavelength range of the light-detecting unit 30, so that the filter 50 can be set to filter out lights having wavelengths outside the most sensitive wavelength range of the light-detecting unit 30, thereby increasing the accuracy of the light-detecting unit 30. It should be noted that the light-detecting unit 30 in each of the aforementioned embodiments of the present invention can be provided with the filter 50 as needed. For instance, when a normal human cells turns into a cancer cell, some specific surface receptor will occur on the surface of cancer cell. After anchor fluorescent molecule on that receptor, the fluorescent molecule will emit light at specific wavelength after being excited at another wavelength. Therefore, the vertical organic light-emitting transistor 20 can be employed to generate a light at specific wavelengths that is emitted to cells in a container. If cancer cells are exist, the fluorescent molecule on the cancer cell will absorb the light and emit another light at another wavelength. The light-detecting unit 30 receives a reflected light from cell for analysis, thereby determining whether or not cytopathic cells, such as cancer cells, exist. The filter 50 is added to remove any light any wavelength except the light at specific wavelength from the fluorescent molecule. Therefore, if light can be detected by the light-detecting unit 30, there are cancer cells in the container. This effectively shortens the time required for diagnosis and examination, allowing a patient to receive more timely treatment and thereby increasing the cure rate.

Referring to FIG. 12, a plurality of the aforementioned light-detecting device structures can be integrated into a matrix structure 60, such as a 4×4 matrix structure, wherein the first vertical transistor 21 or second vertical transistor 23 of the vertical organic light-emitting transistor 20 in each of the light-detecting device structures will drive a corresponding first OLED 22 or second OLED 24 to emit a light. If an object 40 to be detected is placed adjacent to the matrix structure 60, a corresponding light-detecting unit 30 will receive a reflected light from the object 40 to be detected.

For instance, when the vertical organic light-emitting transistor 20 in a light-detecting device structure P11 emits a light, the light-detecting unit 30 in the light-detecting device structure P11 will receive the most reflected light while immediately surrounding light-detecting device structures P6, P7, P8, P10, P12, P14, P15 and P16 receive less reflected light, followed by progressively farther light-detecting device structures. Since the matrix structure 60 composed of the light-detecting device structures can detect a reflected light of an object 40 to be detected over a wide range, the matrix structure 60 can be used to detect a shape of the object 40.

As the light-detecting device structure according to the present invention is a soft electronic device, it can be applied to and comply with a surface of an object 40 and scan words or patterns thereon, so as to improve existing scanners or, still further, be made into a flexible scanner.

The present invention has been described with preferred embodiments thereof. It is understood that the embodiments are intended to allow a person skilled in the art to understand and carry out the content of the present invention, and not intended to limit the scope of the present invention. Therefore, all equivalent changes or modifications which do not depart from the spirit of the present invention should be encompassed by the appended claims.

What is claimed is:

1. A light-detecting device structure, comprising:
a substrate;
a vertical organic light-emitting transistor disposed at a first location on the substrate; and
a light-detecting unit disposed at a second location on the substrate, wherein the first and the second locations are spaced out an appropriate distance.

2. The light-detecting device structure as claimed in claim 1, wherein the substrate is a transparent substrate, a glass substrate or a plastic substrate.

3. The light-detecting device structure as claimed in claim 1, wherein the vertical organic light-emitting transistor comprises:
a first vertical transistor having a first electrode, a first organic layer stacked on the first electrode, and a second electrode combined in the first organic layer; and
a first organic light-emitting diode having a second organic layer stacked vertically on the first vertical transistor, and a third electrode stacked on the second organic layer.

4. The light-detecting device structure as claimed in claim 3, wherein the first electrode or the third electrode is laminated to the substrate.

5. The light-detecting device structure as claimed in claim 3, having the first electrode being an anode, the second electrode being a grid, and the third electrode being a cathode.

6. The light-detecting device structure as claimed in claim 3, having the first electrode being a cathode, the second electrode being a grid, and the third electrode being an anode.

7. The light-detecting device structure as claimed in claim 3, further comprising a fourth electrode disposed between the first organic layer and the second organic layer.

8. The light-detecting device structure as claimed in claim 7, having the first electrode being an anode, the second electrode being a grid, the third electrode being a cathode, and the fourth electrode being an anode.

9. The light-detecting device structure as claimed in claim 7, having the first electrode being a cathode, the second electrode being a grid, the third electrode being an anode, and the fourth electrode being a cathode.

10. The light-detecting device structure as claimed in claim 1, wherein the vertical organic light-emitting transistor comprises:
a second vertical transistor having a fifth electrode, a third organic layer stacked on the fifth electrode, a first insulation layer stacked on the third organic layer, and a sixth electrode stacked on the first insulation layer; and
a second organic light-emitting diode having a fourth organic layer stacked vertically on the second vertical transistor, and a seventh electrode stacked on the fourth organic layer.

11. The light-detecting device structure as claimed in claim 10, wherein the fifth electrode or the seventh electrode is laminated on the substrate.

12. The light-detecting device structure as claimed in claim 10, having the fifth electrode being an anode, the sixth electrode being a base, and the seventh electrode being a cathode.

13. The light-detecting device structure as claimed in claim 10, having the fifth electrode being a cathode, the sixth electrode being a base, and the seventh electrode being an anode.

14. The light-detecting device structure as claimed in claim 10, wherein the second vertical transistor further has a fifth organic layer disposed between the sixth electrode and the fourth organic layer.

15. The light-detecting device structure as claimed in claim 10, wherein the second vertical transistor further has a fifth organic layer and an eighth electrode, in which the fifth organic layer is disposed between the sixth electrode and the eighth electrode while the eighth electrode is disposed between the fifth organic layer and the fourth organic layer.

16. The light-detecting device structure as claimed in claim 15, having the fifth electrode being an anode, the sixth electrode being a base, the seventh electrode being a cathode, and the eighth electrode being an anode.

17. The light-detecting device structure as claimed in claim 15, having the fifth electrode being a cathode, the sixth electrode being a base, the seventh electrode being an anode, and the eighth electrode being a cathode.

18. The light-detecting device structure as claimed in claim 1, wherein the light-detecting unit is a photodiode.

19. The light-detecting device structure as claimed in claim 1, wherein the light-detecting unit further has a filter disposed on the light-detecting unit.

20. The light-detecting device structure as claimed in claim 1, wherein the light-detecting unit further has a filter disposed between the light-detecting unit and the substrate.

21. The light-detecting device structure as claimed in claim 1, wherein the light-detecting unit comprises:
a third vertical transistor having a ninth electrode, a sixth organic layer stacked on the ninth electrode, a tenth electrode combined in the sixth organic layer, and an eleventh electrode stacked on the sixth organic layer;
a light-detecting layer stacked vertically on the third vertical transistor; and
a twelfth electrode stacked on the light-detecting layer.

22. The light-detecting device structure as claimed in claim 21, wherein the ninth electrode or the twelfth electrode is laminated on the substrate.

23. The light-detecting device structure as claimed in claim 21, having the ninth electrode being an anode, the tenth electrode being a grid, the eleventh electrode being a cathode, and the twelfth electrode being an anode.

24. The light-detecting device structure as claimed in claim 21, having the ninth electrode being a cathode, the tenth electrode being a grid, the eleventh electrode being an anode, and the twelfth electrode being a cathode.

25. The light-detecting device structure as claimed in claim 21, further comprising a filter disposed between the light-detecting layer and the third vertical transistor.

26. The light-detecting device structure as claimed in claim 21, further comprising a filter disposed on the twelfth electrode.

27. The light-detecting device structure as claimed in claim 21, further comprising a filter disposed between the twelfth electrode and the substrate.

28. The light-detecting device structure as claimed in claim 1, wherein the light-detecting unit comprises:
a hot carrier transistor having an emitter, a seventh organic layer stacked on the emitter, a second insulation layer stacked on the seventh organic layer, a base stacked on the second insulation layer, an eighth organic layer stacked on the base, and a collector stacked on the eighth organic layer;
a light-detecting layer stacked vertically on the hot carrier transistor; and
a thirteenth electrode stacked on the light-detecting layer.

29. The light-detecting device structure as claimed in claim 28, wherein the emitter or the thirteenth electrode is laminated on the substrate.

30. The light-detecting device structure as claimed in claim 28, having the emitter being an anode, the collector being an anode, and the thirteenth electrode being a cathode.

31. The light-detecting device structure as claimed in claim 28, wherein having emitter being a cathode, the collector being a cathode, and the thirteenth electrode being an anode.

32. The light-detecting device structure as claimed in claim 28, further comprising a filter disposed on the thirteenth electrode.

33. The light-detecting device structure as claimed in claim 28, further comprising a filter disposed between the light-detecting layer and the hot carrier transistor.

34. The light-detecting device structure as claimed in claim 28, further comprising a filter disposed between the thirteenth electrode and the substrate.
